(19) United States
(12) Patent Application Publication
(10) Pub. No.: US 2025/0246443 A1
(43) Pub. Date: Jul. 31, 2025

(54) PACKAGE SUBSTRATE AND MANUFACTURING METHOD THEREOF

(71) Applicant: AaltoSemi Inc., Nanjing City (CN)

(72) Inventors: Yin-Ju CHEN, Nanjing City (CN); Min-Yao CHEN, Nanjing City (CN); Sung-Kun LIN, Nanjing City (CN); Andrew C. CHANG, Nanjing City (CN)

(73) Assignee: AaltoSemi Inc., Nanjing City, JS (CN)

(21) Appl. No.: 19/035,707

(22) Filed: Jan. 23, 2025

(30) Foreign Application Priority Data
Jan. 29, 2024 (CN) 202410122498.2

(51) Int. Cl. H01L 21/48; H01L 23/14; H01L 23/498; H05K 1/02

(52) U.S. Cl. CPC H01L 21/486; H01L 23/49827; H05K 1/0298; H01L 23/145

(57) ABSTRACT

Provided is a package substrate including a dielectric layer having a first surface and a second surface opposite to the first surface; an insulating layer formed on the first surface of the dielectric layer and having a plurality of grooves; a first circuit layer formed in the plurality of grooves and flush with the insulating layer; a second circuit layer formed on the second surface of the dielectric layer; and a plurality of conductive pillars formed in the dielectric layer and electrically connected to the first circuit layer and the second circuit layer. The present disclosure further provides a method of manufacturing the package substrate.

### CROSS-REFERENCE TO RELATED APPLICATION

This application claims the benefit of priority to Chinese Patent Application No. 202410122498.2, filed Jan. 29, 2024, the entire contents of which are hereby incorporated by reference.

### BACKGROUND

### 1. Technical Field

The present disclosure relates to a package substrate and a method of manufacturing the same, and more particularly, to a package substrate and a method of manufacturing the same that avoids side etching and inconsistent depression depth.

### 2. Description of Related Art

With the booming development of the electronics industry, electronic products tend to be thin, light and small, while the functionalities are developing towards the direction of high-performance, high-function and high-speed research and development. Therefore, in order to meet the demand for high integration and miniaturization of semiconductor devices, package substrates having high-density and fine-pitch circuits are often used in the packaging process.

For example, FIG. 1A to FIG. 1F are schematic cross-sectional views showing a conventional manufacturing method of a package substrate 1.

As shown in FIG. 1A, a carrier 9 is provided. A surface of a board body 90 of the carrier 9 has a release layer 91, and a metal layer 92 is formed on the release layer 91. Subsequently, a resistive layer 10 having an opening area 100 is symmetrically formed on two opposite sides of the carrier 9 such that a portion of the surface of the carrier 9 is exposed in the opening area 100.

As shown in FIG. 1B, a first circuit layer 11 is formed on the metal layer 92 of the opening area 100, and subsequently, the resistive layer 10 is removed.

As shown in FIG. 1C, a dielectric layer 12 is formed on the metal layer 92 of the carrier 9, and a plurality of blind vias 120 are formed on the dielectric layer 12.

As shown in FIG. 1D, copper is electroplated on the dielectric layer 12 and in the blind vias 120 to form a second circuit layer 13 on the dielectric layer 12, and a plurality of conductive pillars 14 electrically connected to the first circuit layer 11 and the second circuit layer 13 are formed in the blind vias 120 to form a coreless circuit structure la.

As shown in FIG. 1E, the metal layer 92 is retained on the dielectric layer 12 and the first circuit layer 11 by separating the board body 90 of the carrier 9 from the circuit structure la by the release layer 91.

As shown in FIG. 1F, the metal layer 92 is removed by etching, and partial materials of the first circuit layer 11 are removed by micro-etching at the same time to form a plurality of grooves 15 on the dielectric layer 12.

However, in the conventional package substrate 1, when the metal layer 92 is removed by etching, the first circuit layer 11, 11a is also micro-etched, resulting in inconsistencies in depths D1, D2, D3, D4, D5, and D6 of the grooves 15. It is thus difficult to efficiently bond the solder balls in the grooves 15 during subsequent manufacturing processes, causing poor reliability of the package substrate 1.

Further, since the first circuit layer 11, 11a is also micro-etched when the metal layer 92 is removed by etching, a portion of the first circuit layer 11a may be side-etched, resulting in damage or even breakage of the first circuit layer 11a, thereby signal transmission between the first circuit layer 11a and the solder balls is poor.

Also, since the first circuit layer 11a is prone to damage due to side etching, when the line width/line spacing (L/S) of the first circuit layer 11a is designed to be miniaturized, the first circuit layer 11a is more likely to break, resulting in a signal transmission breakage between the first circuit layer 11a and the solder balls. Hence, the package substrate 1 on which the first circuit layer 11, 11a is miniaturized cannot be mass-produced.

Therefore, there is an urgent need to overcome the aforementioned various problems of the above-mentioned conventional technology.

### SUMMARY

In view of the various shortcomings of the aforementioned conventional technologies, the present disclosure provides a package substrate comprising a dielectric layer having a first surface and a second surface opposite to the first surface; an insulating layer formed on the first surface of the dielectric layer and having a plurality of grooves; a first circuit layer formed in the plurality of grooves and flush with the insulating layer; a second circuit layer formed on the second surface of the dielectric layer; and a plurality of conductive pillars formed in the dielectric layer and electrically connected to the first circuit layer and the second circuit layer.

In the aforementioned package substrate, the insulating layer is a photo-sensitive polyimide.

In the aforementioned package substrate, the plurality of grooves are filled with the first circuit layer.

In the aforementioned package substrate, the plurality of grooves are partially filled with the first circuit layer, and the plurality of grooves are partially filled with the dielectric layer.

The present disclosure further provides a method of manufacturing a package substrate, and the method comprises forming an insulating layer having a plurality of grooves on a metal layer, wherein a portion of the metal layer is exposed from the plurality of grooves, and the metal layer has a plurality of cavities corresponding to the plurality of grooves; forming a barrier layer in the plurality of cavities; forming a first circuit layer on the barrier layer and in the plurality of grooves; forming a dielectric layer on the insulating layer and the first circuit layer, wherein the dielectric layer has a first surface and a second surface opposite to the first surface, and the first surface of the dielectric layer is bonded to the insulating layer; forming a second circuit layer on the second surface of the dielectric layer and forming a plurality of conductive pillars in the dielectric layer for the first circuit layer to be electrically connected to the second circuit layer via the plurality of conductive pillars; and removing the carrier, the metal layer and the barrier layer to expose the first circuit layer, wherein the first circuit layer is flush with the insulating layer.

In the aforementioned manufacturing method of the package substrate, after forming the insulating layer, a portion of the metal layer in the plurality of grooves is removed by etching to form the plurality of cavities.

In the aforementioned manufacturing method of the package substrate, the barrier layer fills the plurality of cavities and is flush with the metal layer.

In the aforementioned manufacturing method of the package substrate, the barrier layer is made of a photo-sensitive material, and the insulating layer is made of a photo-sensitive polyimide.

In the aforementioned manufacturing method of the package substrate, the plurality of grooves are filled with the first circuit layer.

In the aforementioned manufacturing method of the package substrate, the plurality of grooves are partially filled with the first circuit layer, whereby the plurality of grooves are allowed to be partially filled with the dielectric layer.

In summary, in the package substrate and manufacturing method thereof of the present disclosure, the insulating layer having the plurality of grooves is formed on the metal layer, the plurality of cavities corresponding to the plurality of grooves are formed in the metal layer, the barrier layer is formed in the plurality of cavities, and the first circuit layer is formed on the barrier layer. Therefore, with the protection of the barrier layer, the first circuit layer will not be micro-etched when the metal layer is removed, thereby lateral etching of the first circuit layer can be effectively prevented, and a damage (e.g., breakage) to the first circuit layer can be avoided.

Moreover, by the design of the barrier layer flush with the surface of the metal layer, the first circuit layer can be flush with the insulating layer without depression depth. Accordingly, inconsistent depression depth in subsequent manufacturing processes as well as the difficulty in effectively bonding solder balls and the resulted poor reliability of the package substrate can be avoided.

Further, when a line width/line spacing (L/S) of the first circuit layer is designed towards miniaturization, the first circuit layer will not be damaged (e.g., broken) due to side etching, so as to ensure that signals between the first circuit layer and the solder balls can be normally transmitted. As such, the package substrate and manufacturing method thereof of the present disclosure are advantageous for mass production of package substrates requiring miniaturization of the first circuit layer.

### BRIEF DESCRIPTION OF THE DRAWINGS

The present disclosure can be more fully understood by reading the following description of the embodiments, with reference made to the accompanying drawings, in which:

FIG. 1A to FIG. 1F are schematic cross-sectional views showing a conventional manufacturing method of a package substrate.

FIG. 2A to FIG. 2I are schematic cross-sectional views showing a method of manufacturing a package substrate according to the present disclosure.

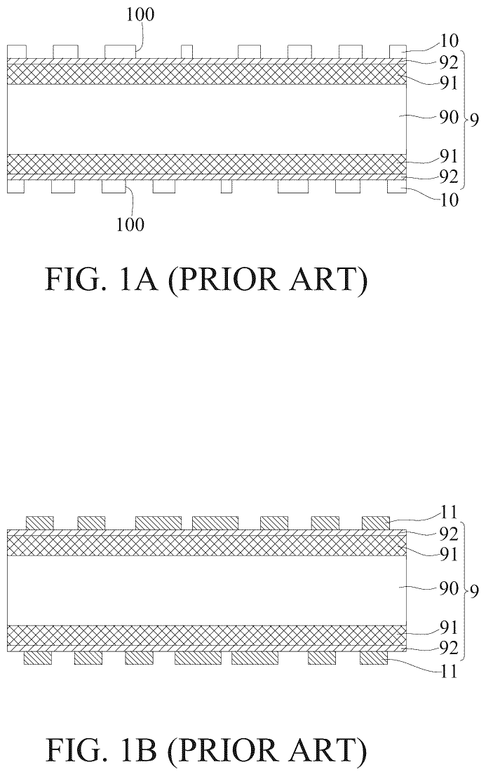

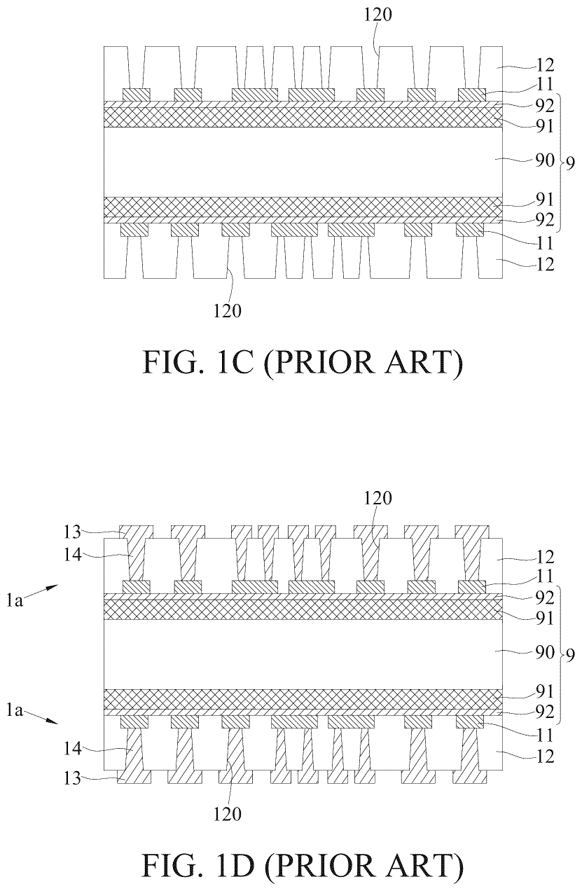

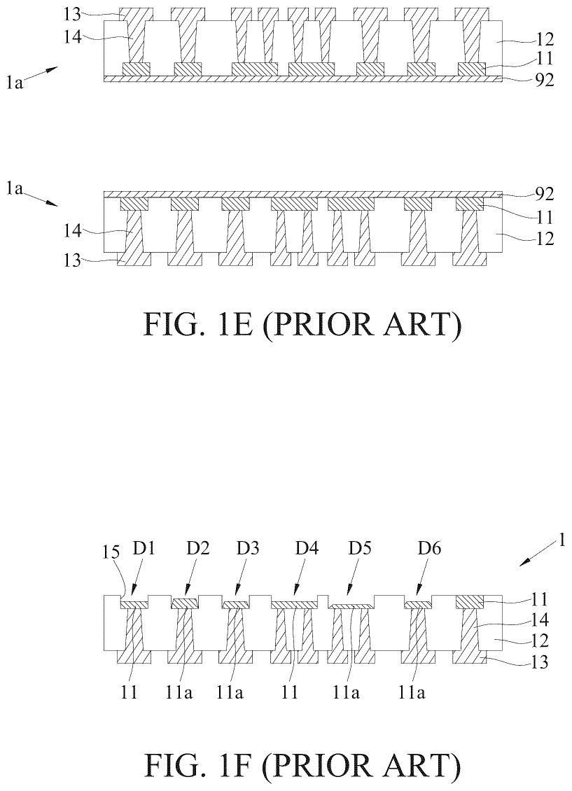

### DETAILED DESCRIPTION

The following describes the implementation of the present disclosure with examples. Those skilled in the art can easily understand other advantages and effects of the present disclosure from the content disclosed in this specification.

Note, the structures, proportions, dimensions, etc. shown in the figures attached to the present specification are only for the purpose of assisting one having ordinary skill in the technical field to understand and read, and are not intended to be limiting conditions of the present disclosure, and therefore do not have technical substantive significance. It should be understood that the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “first,” “second,” “upper,” and “lower” recited in the specification are used for clear description, the change or adjustment of their relative relationship without substantial alteration of the technical contents are also considered within the implementation scope of the present disclosure. Furthermore, all ranges and values recited in the present disclosure are inclusive and combinable.

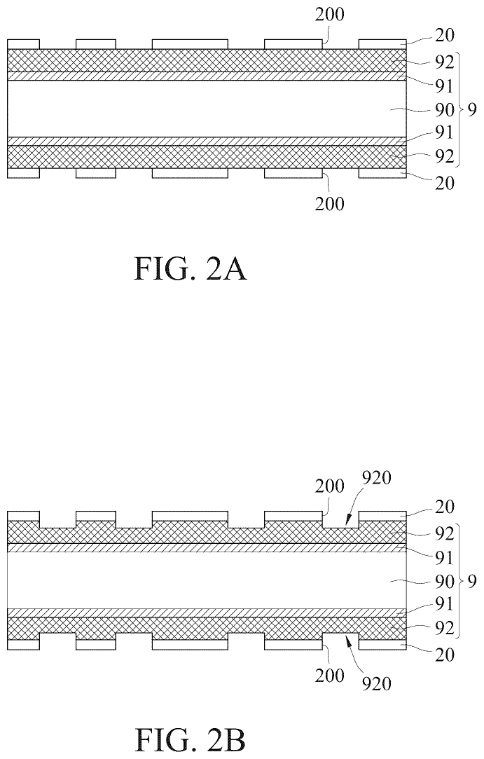

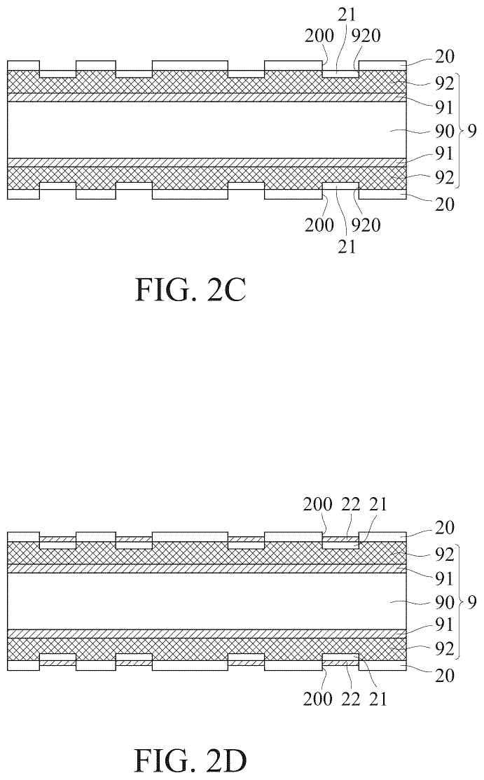

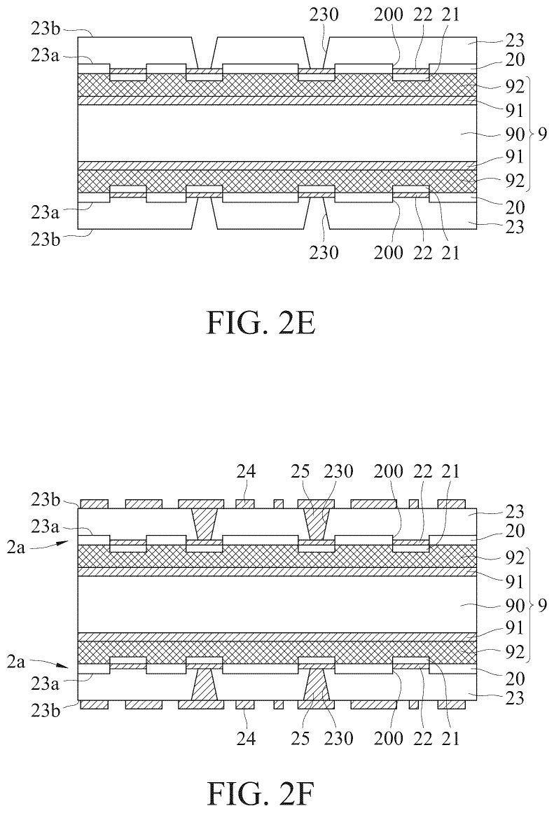

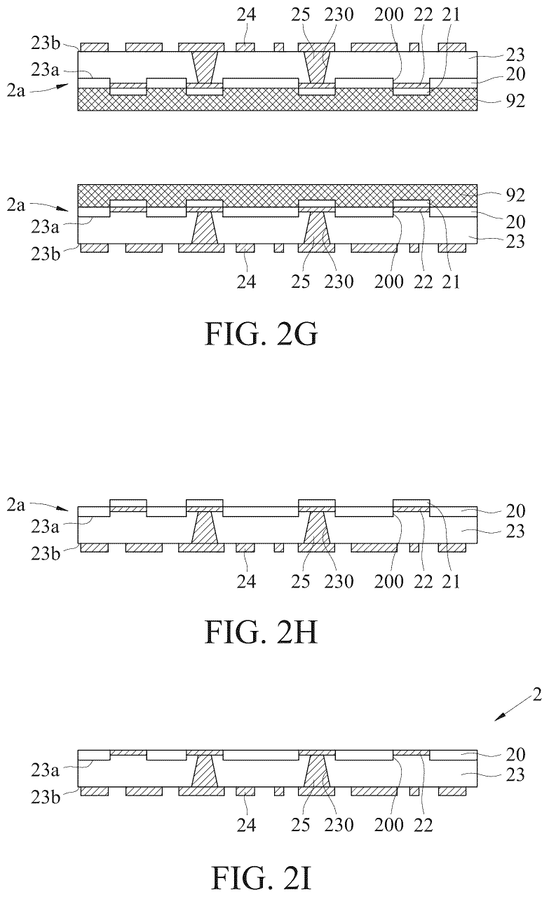

FIG. 2A to FIG. 2I are schematic cross-sectional view showing a method of manufacturing a package substrate 2 according to the present disclosure.

As shown in FIG. 2A, a carrier 9 is provided to symmetrically form an insulating layer 20 having a plurality of grooves 200 on two opposite sides of the carrier 9 such that a portion of the surfaces of the carrier 9 is exposed in the plurality of grooves 200.

In this embodiment, the carrier 9 is a temporary carrier board, and a board body 90 thereof may be, for example, an organic polymer board including a bismaleimide triazine (BT), a prepreg (PP) with glass fiber or other board. Surfaces of the board body 90 have release layers 91 which may be made of, for example, copper, and metal layers 92 (e.g., copper layers) are formed on the release layers 91 such that the insulating layers 20 are formed on the metal layer 92.

Moreover, the insulating layer 20 is a photosensitive polyimide (PSPI) having a high resolution, which is capable of forming a high-density pattern and is advantageous for designing the line width/line spacing (L/S) of the subsequent first circuit layer 22 towards miniaturization. Accordingly, the plurality of grooves 200 can be formed by using an exposure developing method such that a portion of the metal layer 92 is exposed in the plurality of grooves 200.

In an embodiment, a thickness of the metal layer 92 is 18 μm, and a thickness of the release layer 91 is 3 μm, but the present disclosure is not limited thereto.

As shown in FIG. 2B, a portion of the metal layer 92 in the plurality of grooves 200 is removed by using an etching method to form a plurality of cavities 920 corresponding to the plurality of grooves 200. In an embodiment, a depth of the cavities 920 after etching is smaller than a given thickness of the metal layer 92. In some embodiments, a depth of the cavities 920 is 6 μm to 12 μm, but not limited thereto.

As shown in FIG. 2C, a barrier layer 21 is formed in the plurality of cavities 920.

In an embodiment, the barrier layer 21 can be formed in the cavities 920 by roller coating or spraying, and the barrier layer 21 can fill the cavities 920 and be flush with the surface of the metal layer 92.

Further, in an embodiment, the barrier layer 21 is a liquid type solder mask but is not limited thereto. Other materials such as a dry film type solder mask or any photographic type material can also be used as the material of the barrier layer 21.

As shown in FIG. 2D, metal materials (e.g., copper) are formed in the plurality of grooves 200 by plating or sputtering, which are served as the first circuit layers 22.

In an embodiment, the grooves 200 are partially filled with the first circuit layer 22 such that the first circuit layer 22 is recessed in the surface of the insulating layer 20. That is, the thickness of the first circuit layer 22 is smaller than the thickness of the insulating layer 20. In other embodiments, the grooves 200 may also be completely filled with the first circuit layer 22 such that the thickness of the first circuit layer 22 is equal to the thickness of the insulating layer 20, and the first circuit layer 22 is flush with the surface of the insulating layer 20. In addition, the first circuit layer 22 adopts a circuit redistribution layer (RDL) specification.

As shown in FIG. 2E, dielectric layers 23 are formed on the insulating layers 20 and the first circuit layers 22, and the dielectric layers 23 are defined with first surfaces 23a and second surfaces 23b opposite to the first surfaces 23a such that the first surfaces 23a of the dielectric layers 23 are bonded to the insulating layers 20, and a plurality of blind vias 230 exposing the first circuit layers 22 are formed on the second surfaces 23b of the dielectric layers 23 by laser.

In this embodiment, the dielectric layer 23 is a dielectric material, such as ajinomoto build-up film (ABF), polybenzoxazole (PBO), polyimide (PI), prepreg (PP) with glass fibers, or others.

Further, if the grooves 200 are partially filled with the first circuit layer 22, the grooves 200 may be partially filled with the dielectric layer 23 such that the first surface 23a of the dielectric layer 23 has a segmental difference at the edge of the grooves 200. Alternatively, if the grooves 200 are completely filled with the first circuit layer 22, the grooves 200 will not be filled with the dielectric layer 23.

As shown in FIG. 2F, second circuit layers 24 are formed on the second surfaces 23b of the dielectric layers 23, and a plurality of conductive pillars 25 electrically connected to the first circuit layers 22 and the second circuit layers 24 are formed in the blind vias 230 to form coreless circuit structures 2a.

In this embodiment, the second circuit layer 24 is manufactured by electroplating metal (e.g., copper) or other means using a build-up process. For example, copper is electroplated on the dielectric layer 23 and in the blind vias 230 to integrally form the second circuit layer 24 and the conductive pillars 25.

Moreover, the second circuit layer 24 is made of copper. For example, the second circuit layer 24 adopts a circuit redistribution layer (RDL) specification.

It should be appreciated that by utilizing a build-up method, the circuit structure 2a may be designed with the number of layers of the dielectric layer 23 as required so as to manufacture the second circuit layer 24 with the required number of layers.

As shown in FIG. 2G, the board body 90 of the carrier 9 is separated from the circuit structures 2a by the release layers 91 to retain the metal layers 92 on the insulating layers 20.

In an embodiment, the release layer 91 is removed by a peeling off method or other methods to separate the board body 90 from the metal layer 92.

As shown in FIG. 2H, the metal layer 92 is removed by etching to expose the barrier layer 21.

As shown in FIG. 2I, the barrier layer 21 is removed such that the first circuit layer 22 is exposed to the insulating layer 20 and is flush with the surface of the insulating layer 20.

In an embodiment, the barrier layer 21 may be removed by using 1% sodium carbonate (NaCO₃).

It should be understood that in a subsequent process, a plurality of solder balls bonded to and electrically connected to the first circuit layer 22 may be provided on the insulating layer 20 such that the package substrate 2 is connected to an electronic device such as a semiconductor chip, a passive component, a silicon intermediary board, a circuit board, or other components by means of the plurality of solder balls, thereby forming an electronic package.

The present disclosure also provides the package substrate 2 as shown in, for example, FIG. 2I. The package substrate 2 includes the insulating layer 20, the first circuit layer 22, the dielectric layer 23, the second circuit layer 24 and the plurality of conductive pillars 25.

The insulating layer 20 has the plurality of grooves 200, and the first circuit layer 22 is formed in the plurality of grooves 200. In an embodiment shown in FIG. 2I, the plurality of grooves 200 are apertures penetrating through the insulating layer 20, and the first circuit layer 22 is formed in the plurality of apertures and is flush with the insulating layer 20, that is, flush with the surface of the insulating layer 20 that corresponds to an outer surface of the package substrate 2.

In an embodiment, the insulating layer 20 is a photo-sensitive polyimide (PSPI) with a high resolution, and the first circuit layer 22 is formed by electroplating or sputtering a metallic material (e.g., copper) in the plurality of grooves 200.

Further, the grooves 200 are partially filled with the first circuit layer 22 such that the first circuit layer 22 is recessed in one surface of the insulating layer 20 but is flush with another surface of the insulating layer 20. That is, the thickness of the first circuit layer 22 is smaller than the thickness of the insulating layer 20. In other embodiments, the grooves 200 may also be completely filled with the first circuit layer 22 such that the thickness of the first circuit layer 22 is equal to the thickness of the insulating layer 20, and the first circuit layer 22 is flush with the surface of the insulating layer 20.

The dielectric layer 23 has the first surface 23a, the second surface 23b opposite to the first surface 23a and the plurality of blind vias 230, and the first surface 23a is bonded to the insulating layer 20 and the first circuit layer 22. The plurality of blind vias 230 penetrate through the first surface 23a and the second surface 23b and expose the first circuit layer 22.

The second circuit layer 24 is formed on the second surface 23b of the dielectric layer 23. The plurality of conductive pillars 25 are formed in the plurality of blind vias 230 to electrically connect the first circuit layer 22 and the second circuit layer 24.

In an embodiment, this first circuit layer 22 and the second circuit layer 24 adopt a circuit redistribution layer (RDL) specification. It should be appreciated that the second circuit layer 24 and the conductive pillars 25 may be formed together or separately.

It should be appreciated that by utilizing the build-up method, the number of layers of the dielectric layer 23 can be designed according to the demand, so as to manufacture the desired number of layers of the second circuit layer 24.

In summary, in the package substrate and manufacturing method thereof of the present disclosure, the insulating layer having the plurality of grooves is formed on the metal layer, the plurality of cavities corresponding to the plurality of grooves are formed in the metal layer, the barrier layer is formed in the plurality of cavities, and the first circuit layer is formed on the barrier layer. Therefore, with the protection of the barrier layer, the first circuit layer will not be micro-etched when the metal layer is removed, thereby lateral etching of the first circuit layer can be effectively prevented, and an damage (e.g., breakage) to the first circuit layer can be avoided.

Moreover, by the design of the barrier layer flush with the surface of the metal layer, the first circuit layer can be flush with the insulating layer without depression depth. Accordingly, inconsistent depression depth in subsequent manufacturing processes as well as the difficulty in effectively bonding solder balls and the resulted poor reliability of the package substrate can be avoided.

Further, when a line width/line spacing (L/S) of the first circuit layer is designed towards miniaturization, the first circuit layer will not be damaged (e.g., broken) due to side etching, so as to ensure that signals between the first circuit layer and the solder balls can be normally transmitted. As such, the package substrate and manufacturing method thereof of the present disclosure are advantageous for mass production of package substrates requiring miniaturization of the first circuit layer.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate comprising:
a dielectric layer having a first surface and a second surface opposite to the first surface;
an insulating layer formed on the first surface of the dielectric layer and having a plurality of grooves;
a first circuit layer formed in the plurality of grooves and flush with the insulating layer;
a second circuit layer formed on the second surface of the dielectric layer; and
a plurality of conductive pillars formed in the dielectric layer and electrically connected to the first circuit layer and the second circuit layer.

2. The package substrate of claim 1, wherein the insulating layer is formed of a photo-sensitive polyimide.

3. The package substrate of claim 1, wherein the plurality of grooves are filled with the first circuit layer.

4. The package substrate of claim 1, wherein the plurality of grooves are partially filled with the first circuit layer, whereby the plurality of grooves are allowed to be partially filled with the dielectric layer.

5. A method of manufacturing a package substrate, comprising:
forming an insulating layer having a plurality of grooves on a metal layer, wherein the grooves expose the metal layer, and the metal layer has a plurality of cavities corresponding to the plurality of grooves;
forming a barrier layer in the plurality of cavities;
forming a first circuit layer on the barrier layer and in the plurality of grooves;
forming a dielectric layer on the insulating layer and the first circuit layer, wherein the dielectric layer has a first surface and a second surface opposite to the first surface, such that the first surface of the dielectric layer is bonded to the insulating layer;
forming a second circuit layer on the second surface of the dielectric layer and forming a plurality of conductive pillars in the dielectric layer for the first circuit layer to be electrically connected to the second circuit layer via the plurality of conductive pillars; and
removing the carrier, the metal layer and the barrier layer to expose the first circuit layer, wherein the first circuit layer is flush with the insulating layer.

6. The method of claim 5, wherein after forming the insulating layer, a portion of the metal layer in the plurality of grooves is removed by etching to form the plurality of cavities.

7. The method of claim 5, wherein the barrier layer fills the plurality of cavities and is flush with the metal layer.

8. The method of claim 5, wherein the barrier layer is made of a photo-sensitive material, and the insulating layer is made of a photo-sensitive polyimide.

9. The method of claim 5, wherein the plurality of grooves are filled with the first circuit layer.

10. The method of claim 5, wherein the plurality of grooves are partially filled with the first circuit layer, whereby the plurality of grooves are allowed to be partially filled with the dielectric layer.
